(19) United States
(12) Patent Application Publication
(10) Pub. No.: US 2008/0150030 A1
(43) Pub. Date: Jun. 26, 2008

(54) SEMICONDUCTOR DEVICE AND MANUFACTURING METHOD OF THE SAME

(75) Inventors: Shigeyuki YOKOYAMA, Tokyo (JP); Yu Kosuge, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 11/959,070

(22) Filed: Dec. 18, 2007

(30) Foreign Application Priority Data
Dec. 26, 2006 (JP) 2006-348967

(51) Int. Cl. H01L 29/78; H01L 21/336

(52) U.S. Cl. 257/365; 438/283; 257/E21.421; 257/E29.264

(57) ABSTRACT

A semiconductor device includes a double gate transistor which comprises an active region of a fin type and a pair of gate electrodes disposed opposite to each other through the active region. A height of the gate electrodes is higher than that of the active region and equal to or smaller than a calculated gate electrode height calculated using the following formula:

$$( ( Gate Electrode Height [ nm ] ) - ( Active Region Height [ nm ] ) ) / ( Active Region Height [ nm ] ) = 3.5 {e}^{- 5} \times {( Gate Length [ nm ] )}^{2} - 0.002 \times ( Gate Length [ nm ] ) + 0.16 .$$

This application is based upon and claims the benefit of priority from Japanese patent application No. 2006-348987, filed on Dec. 26, 2006, the disclosure of which is incorporated herein in its entirety by reference.

### BACKGROUND OF THE INVENTION

This invention relates to a semiconductor device and a manufacturing method thereof, in particular, to a semiconductor device including a double gate transistor and a manufacturing method thereof.

A double gate transistor has a pair of gate electrodes formed on both sides of a fin-type active region, which is formed to be protruded, through insulating films so as to be opposite to each other through the active region.

By employing such a structure, the double gate transistor can not only suppress the short channel effect but also improve subthreshold characteristics. Further, the double gate transistor can enlarge an effective gate width in comparison with a planar type transistor having the same projected area because channels are formed at the both sides of the active region. Thereby, a driving current of the double gate transistor can be increased.

A related double gate transistor is configured so that a height of the gate electrodes is equal to that of the active region to bring out the advantages mentioned above.

Such a double gate transistor is disclosed in PCT Japanese Translation Patent Publication No. 2006-500786.

### SUMMARY OF THE INVENTION

The related double gate transistor is configured so that the height of the gate electrodes is equal to that of the active region as mentioned above. This depends on the following reasons.

FIGS. 1A and 1B show sectional views of double gate transistors individually. In each of FIGS. 1A and 1B, the double gate transistor includes a silicon (Si) substrate 501 with an active region formed to be protruded, an element isolation oxide film 502, gate oxide films 503 formed on side surfaces of the active region, a nitride film 504 formed on the active region through an underlayer oxide film, and a pair of gate electrodes 505. It should be noted that the nitride film 504 is omitted in FIG. 1B.

As illustrated in FIG. 1A, in a case where the height H_{G} of the gate electrodes 505 is higher than the height H_{A} of the active region, electric fields from the gate electrodes 505 are concentrated at edges of an upper surface of the active region and threshold voltage is partly reduced thereat.

On the other hand, as shown in FIG. 1B, in a case where the height H_{G} of the gate electrodes 505 is lower than the height H_{A} of the active region, depletion layers are extended to upper portions, which are not changed into channels 506, of the active region. Therefore, widths of the depletion layers are reduced in a direction perpendicular to the gate electrodes (i.e. a direction of right and left of the drawing) and thereby it becomes difficult to operate as a fully depleted type transistor.

For reasons mentioned above, the related double gate transistor is configured so that the height H_{G} of the gate electrodes is equal to the height H_{A} of the active region.

However, it is difficult to match the height H_{G} of the gate electrodes with the height H_{A} of the active region with a high degree of accuracy and thus there is a problem that a margin in a manufacturing process of a device is narrow.

It is therefore an object of this invention to provide a semiconductor device having a wide margin in the manufacturing process thereof without reducing device characteristics.

Inventors have found that the threshold voltage becomes rapidly increased as the height of the gate electrodes becomes lower than that of the active region. Inventors further have found that if the height of gate electrodes is higher than that of the active region by a few or dozens percent, concentration of the electric fields is not occurred, adverse depletion layers are not formed, variation of the threshold voltage is gradual when the height difference between the gate electrodes and the active region is in a certain range, and an on-current of the transistor is increased when the height difference is in the range. This means that the process margin of a case where the gate electrodes are lower than the active region is very small in comparison with that of a case where the gate electrodes are higher than the active region, in a case where the gate electrodes are made to have the same height as that of the active region. Accordingly, if the gate electrodes are designed to have the height higher than that of the active region in some degree, it will be possible to increase the process margin of the case where the gate electrodes is lower than that of the active region. Thereby, it is possible to increase practical process margin.

According to an aspect of this invention, there is provided a semiconductor device including a double gate transistor. The double gate transistor includes an active region of a fin type and a pair of gate electrodes disposed opposite to each other through the active region. A height of the gate electrodes is higher than a height of the active region so as to obtain an on-current larger than that of a case where the height of the gate electrodes is equal to the height of the active region.

It is desirable that the height of the gate electrodes is higher than that of the active region by a few or dozen percent. However, a desirable height of the gate electrodes depends on a gate length. Therefore, the height of the gate electrodes is decided so as to be equal to or lower than a calculated gate electrode height calculated using the following formula.

$$( ( Gate Electrode Height [ nm ] ) - ( Active Region Height [ nm ] ) ) / ( Active Region Height [ nm ] ) = 3.5 {e}^{- 5} \times {( Gate Length [ nm ] )}^{2} - 0.002 \times ( Gate Length [ nm ] ) + 0.16$$

According to another aspect of this invention, there is a manufacturing method of a semiconductor device which includes a double gate transistor. The double gate transistor includes an active region of a fin type and a pair of gate electrodes disposed opposite to each other through the active region. The manufacturing method includes steps of adjusting, to a predetermined value, a thickness of a hard mask which is formed on the active region and used for forming the active region; forming an electrode layer for the gate electrodes; polishing the electrode layer so that a position of an upper surface thereof is matched with that of an upper surface of the hard mask to form the gate electrodes.

The predetermined value is determined so that a height of the gate electrodes is equal to or smaller than a calculated gate electrode height calculated using the following formula.

$$( ( Gate Electrode Height [ nm ] ) - ( Active Region Height [ nm ] ) ) / ( Active Region Height [ nm ] ) = 3.5 {e}^{- 5} \times {( Gate Length [ nm ] )}^{2} - 0.002 \times ( Gate Length [ nm ] ) + 0.16$$

### BRIEF DESCRIPTION OF THE DRAWINGS

FIG. 1A is a sectional view for describing a problem in a double gate transistor with gate electrodes having a height higher than that of an active region;

FIG. 1B is a sectional view for describing a problem in a double gate transistor with gate electrodes having a height lower than that of an active region;

FIG. 2A is a schematic perspective view of a semiconductor device according to a preferred embodiment of this invention;

FIG. 2B is a sectional view taken along a direction parallel with a gate;

FIG. 3 is a graph of a threshold voltage and an on-current to percentage of a height of gate electrodes to a height of an active region;

FIG. 4 is a graph of a margin for a height of gate electrodes to a gate length;

FIG. 5 is a perspective view for describing a manufacturing process for the semiconductor device of FIGS. 2A and 2B;

FIG. 6 is a perspective view for describing a manufacturing process succeeding the process of FIG. 5;

FIG. 7 is a perspective view for describing a manufacturing process succeeding the process of FIG. 6;

FIG. 8 is a perspective view for describing a manufacturing process succeeding the process of FIG. 7;

FIG. 9 is a perspective view for describing a manufacturing process succeeding the process of FIG. 8;

FIG. 10 is a perspective view for describing a manufacturing process succeeding the process of FIG. 9;

FIG. 11 is a perspective view for describing a manufacturing process succeeding the process of FIG. 10;

FIG. 12 is a perspective view for describing a manufacturing process succeeding the process of FIG. 11;

FIG. 13 is a perspective view for describing a manufacturing process succeeding the process of FIG. 12;

FIG. 14 is a perspective view for describing a manufacturing process succeeding the process of FIG. 13; and

FIG. 15 is a perspective view of the semiconductor device finished by a manufacturing process succeeding the process of FIG. 14.

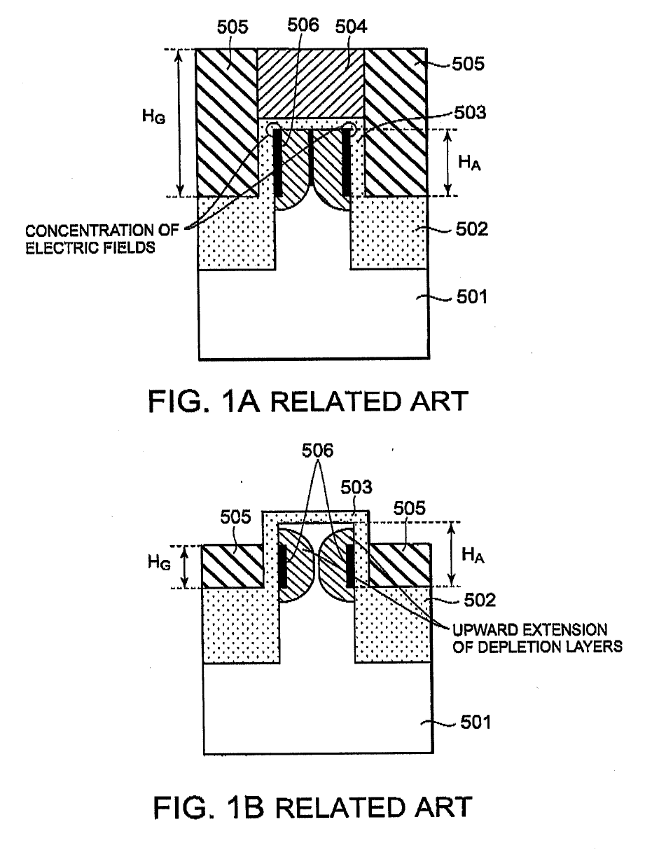

### DESCRIPTION OF THE PREFERRED EMBODIMENT

The description will be made about a semiconductor device according to a preferred embodiment of this invention with reference to attached drawings.

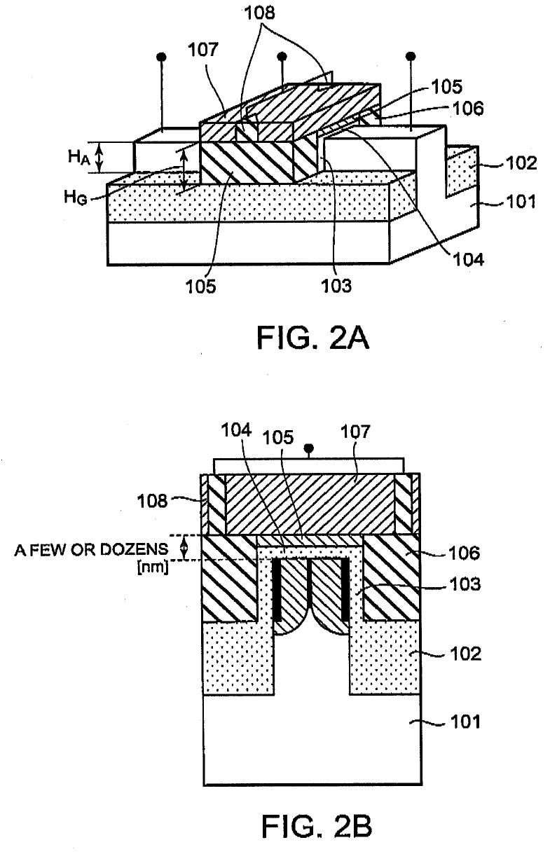

FIG. 2A is a schematic perspective view of the semiconductor device while FIG. 2B is a sectional view taken along a direction parallel to a gate thereof. The illustrated semiconductor device is a double gate transistor which may be used as a transistor for CMOS, a memory cell driving transistor for DRAM or the like.

The illustrated double gate transistor includes a silicon substrate 101, an element isolation region (or an oxide film) 102, gate oxide films 103, an underlayer oxide film 104, a nitride film 105, gate electrodes 106, interlayer insulating film 107 and contacts 108.

The silicon substrate 101 has a part protruding from the element isolation region 102 as an active region of a fin type. The active region is doped into p-type before the element isolation region 102 is formed.

The nitride film 105 is a hard mask which has been used for forming the element isolation region 102 and has not removed by subsequent steps and remains together with the underlayer oxide film 104. As mentioned later, the underlayer oxide film 104 and the nitride film 105 are used to make a height H_{G} of the gate electrodes higher than a height H_{A} of the active region.

The gate oxide films 103 are formed on both side surfaces of the active region. A pair of the gate electrodes 106 is made of n-type polycrystalline silicon and formed to sandwich the active region between them through the gate oxide films 103. Upper surfaces of the gate electrodes 106 are polished by chemical mechanical polishing (CMP) method at formation thereof and have the same height as that of the nitride film 105. That is, the height of the gate electrodes 106 is higher than that of the active region by a total film thickness (of a few or dozens nanometers) of the underlayer oxide film 104 and the nitride film 105.

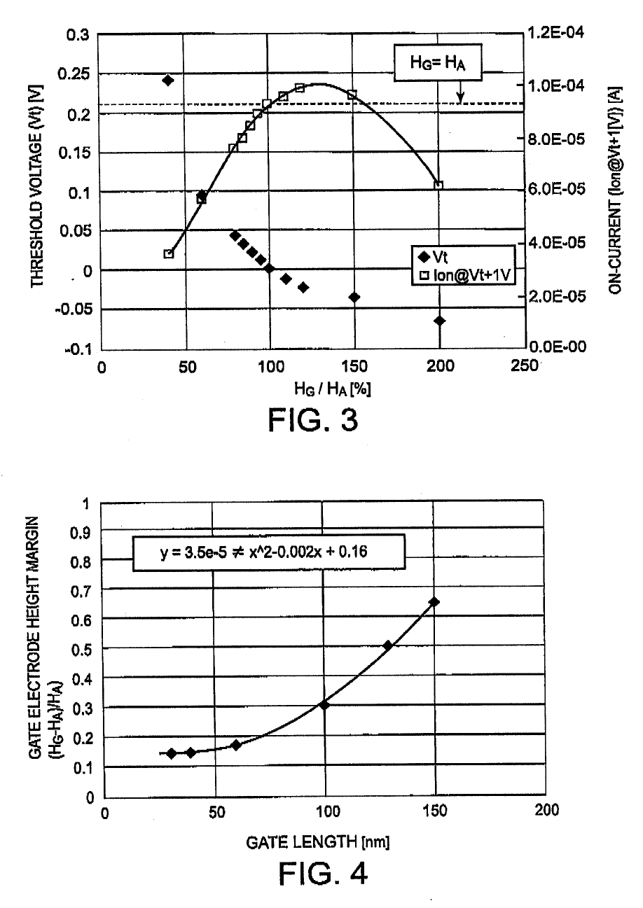

FIG. 3 shows relationships between a threshold voltage or an on-current and a percentage of a height of gate electrodes to a height of an active region. Here, the on-current represents a drain current when a gate voltage higher than the threshold voltage Vt by 1 [V] is impressed.

As illustrated in FIG. 3, there is a range of a large on-current which is large in comparison with a case where the height of the gate electrodes is equal to that of the active region. In the range, the height of the gate electrodes is higher than that of the active region by a few or dozens percent. In the range, variation of the threshold voltage is gradual, concentration of electric fields is not occurred and adverse depletion layers are not formed. Therefore, in this embodiment, the height H_{G} of the gate electrodes is decided so that the ratio of the height H_{G} of the gate electrodes to the height H_{A} of the active region is in the range.

Specifically, the gate electrode height H_{G} bringing an objective process margin depends on the gate length and varies as shown in FIG. 4. Therefore, the maximum value of the gate electrode height H_{G} is determined by the use of the following (experimental) formula 1.

$$( ( Gate Electrode Height [ nm ] ) - ( Active Region Height [ nm ] ) ) / ( Active Region Height [ nm ] ) = 3.5 {e}^{- 5} \times {( Gate Length [ nm ] )}^{2} - 0.002 \times ( Gate Length [ nm ] ) + 0.16 \qquad ( Formula 1 )$$

Because the semiconductor device of this embodiment has the structure that the height H_{G} of the gate electrodes is higher than the height H_{A} of the active region by a few or dozens percent, it can widen the process margin without reduction of transistor performance or characteristics.

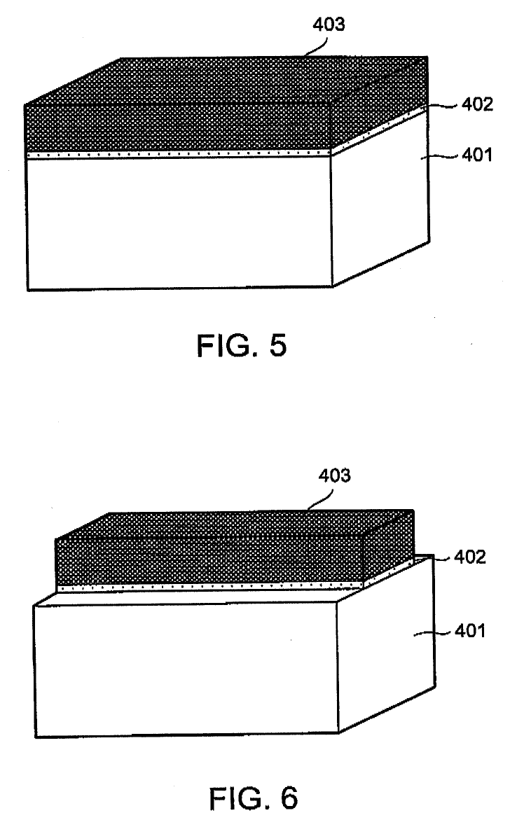

Hereinafter, a manufacturing method of the semiconductor device of FIGS. 2A and 2B will be described with reference to FIGS. 5 to 15.

At first, as illustrated in FIG. 5, a silicon substrate 401 doped into p-type is prepared. A thermal oxide film 402 having a thickness of about 5 nm is formed on the silicon substrate 401 and then a nitride film 403 having a thickness of about 100 nm is deposited on the thermal oxide film 402.

Next, using lithography and dry etching, as illustrated in FIG. 6, the nitride film 403 and the thermal oxide film 402 is processed into a mask shape.

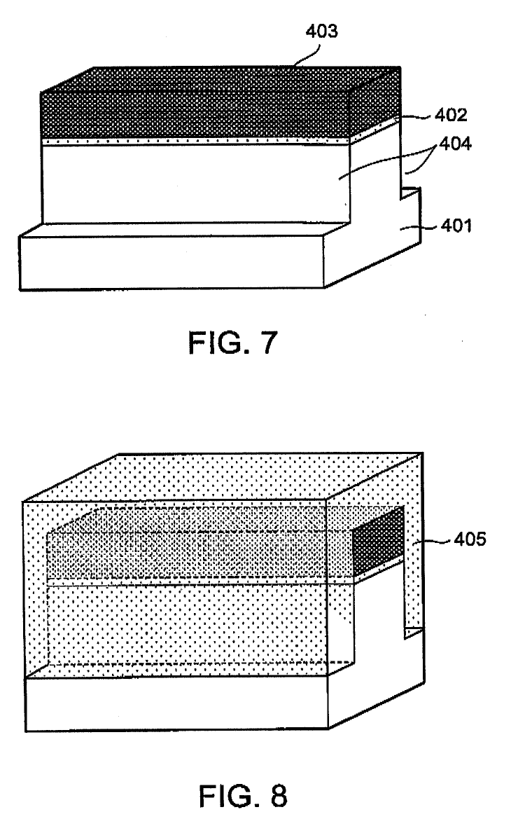

Using the nitride film 403 as a hard mask, the silicon substrate 401 is etched to form element isolation regions 404 as shown in FIG. 7.

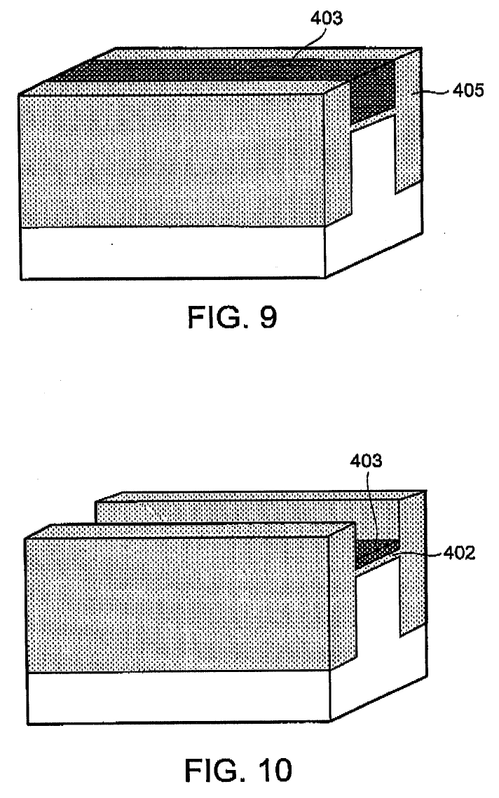

Next, as illustrated in FIG. 8, the element isolation regions 404 are embedded with an oxide film 406. Using the nitride film 403 as an end point detection film, the oxide film 405 is polished and flattened by means of chemical mechanical polishing (CMP) method. Thereby, as illustrated in FIG. 9, the surface of the oxide film 405 is matched with that of the nitride film 403.

Next, the nitride film 403 is etched by hot phosphoric acid to reduce the thickness thereof as shown in FIG. 10. Etching amount of the nitride film 403 can be voluntarily controlled by changing etching conditions.

The following formula 2 stands up between a total thickness of the etched nitride film 403 and the oxide film 402 and “(Gate Electrode Height)−(Active Region Height)” of Formula 1.

(Thickness of Nitride Film 403)+(Thickness of Oxide Film 402)=(Gate Electrode Height)−(Active Region Height) (Formula 2)

If the gate length is 50 nm and the height of the active region is 100 nm, it is necessary that the total thickness of the nitride film 403 and the oxide film 402 be equal to or less than 15 nm so that the formula 2 is kept. Here, if the oxide film 402 has a thickness of 5 nm, etching time for the nitride film 403 may be controlled so that the nitride film 403 has a thickness equal to or less than 10 nm. Concretely, the etching using the hot phosphoric acid of 180° C. for 8 minutes and 10 seconds reduces the thickness of the nitride film 403 in 10 nm. As a result, the total thickness of the nitride film 403 and the oxide film 402 becomes equal to 15 nm and thereby the formula 1 is satisfied. In this case, the margin for the etching time is about 30 seconds and sufficiently wide.

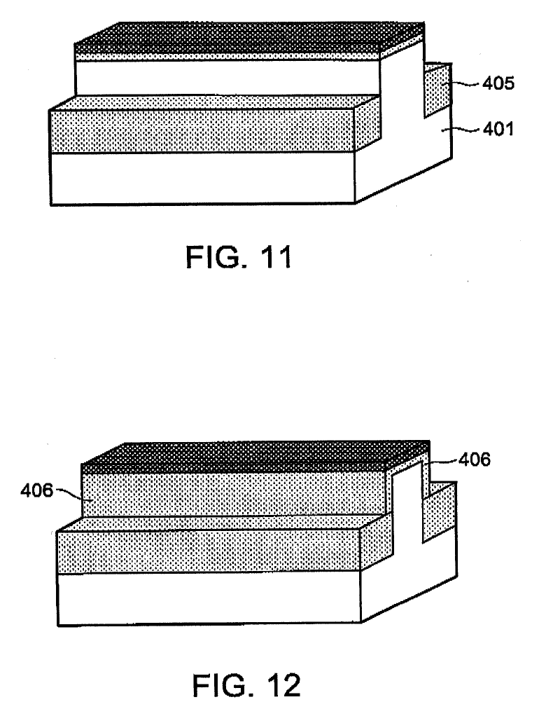

Next, as illustrated in FIG. 11, the element isolation film 405 is etched by dilute hydrofluoric acid to protrude a part, as the active region, of the silicon substrate 401 from the element isolation film 405. The protruded active region has a height of from dozens to about 100 nm and a width of dozens nm.

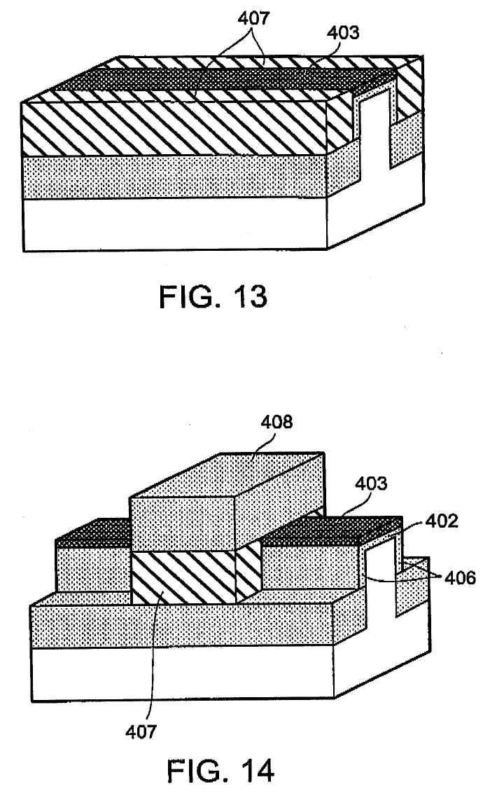

Next, as illustrated in FIG. 12, the gate oxide films 406 each of which has a thickness of a few nm are formed on the side surfaces of the active region by thermal oxidation. Subsequently, as illustrated in FIG. 13, n-type polycrystalline silicon 407 for the gate electrodes is deposited and then the surface thereof is flattened. The flattening process is performed by polishing the surface of the polycrystalline silicon 407 using COMP method and the nitride film 403 as an end point detection film. Thus, the upper surfaces (or a position thereof) of the gate electrodes are matched with that of the hard mask (i.e. the nitride film 403).

As mentioned above, the thickness of the nitride film 403 is voluntarily adjusted by changing the etching conditions. By using the nitride film 403 with an adjusted thickness as the end point detection film for the polishing of the polycrystalline silicon 407 (i.e. gate electrodes), the height of the gate electrodes can be voluntarily adjusted. That is, it is possible to make the height H_{G} of the gate electrodes higher than the height H_{A} of the active region by a few or dozens percent.

Next, as illustrated in FIG. 14, an oxide film 408 is formed as a hard mask. Using the hard mask, the polycrystalline silicon 407 is patterned (or dry etched) to form the gate electrodes.

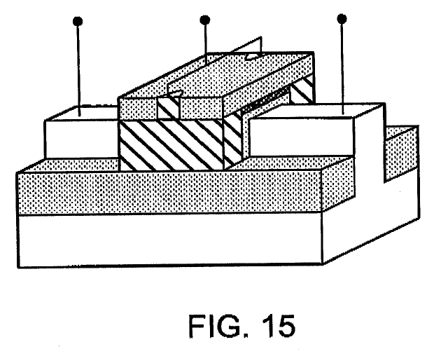

Next, the nitride film 403, the underlayer oxide film 402 and the gate oxide films 406 are removed by wet etching except for parts covered by the gate electrodes and the hard mask 408. N-type impurities are ion implanted into exposed portions of the active region to form source and drain regions. Thereafter, an interlayer insulating film is deposited and then contacts are provided at the gate, the source and the drain regions. Thus, the double gate transistor as shown in FIG. 15 is completed.

As described above, the double gate transistor of FIGS. 2A and 2B can be manufactured.

According to the embodiment, the thickness of the hard mask used for forming the active region is adjusted according to Formula 1. Further, the polycrystalline silicon for the gate electrodes is polished using the adjusted hard mask as the end point detection film. Thereby the height of the gate electrodes can be certainly limited in a range defined by Formula 1. Therefore, in the completed double gate transistor, it is possible to suppress concentration of electric fields and formation of adverse depletion layers and thereby obtaining good performance or characteristics.

Furthermore, according to the embodiment, the height of the gate electrodes which is decided using Formula 1 is in a range that the threshold voltage is gradually varied against variation of the height of the gate electrodes. Therefore, wide process margin can be obtained for process dispersion of the height of the gate electrodes.

While this invention has thus far been described in conjunction with the preferred embodiment thereof, this invention is not limited to the embodiment and it will readily be possible for those skilled in the art to put this invention into practice in various other manners.

For example, after the polycrystalline silicon for the gate electrodes is dry etched, an oxidization process may be performed to thicken the gate oxide film (or to form bird's beaks) at gate edges. Herewith, an electric field at an edge of the drain can be relaxed when the device operates.

Moreover, to form the source and the drain, plasma doping may be used as substitute for ion implantation. Alternatively, for the source and the drain, lightly doped drain (LDD) structure may be employed. The LDD structure is formed by ion implanting impurities at relatively low concentrations, depositing an oxide film with a thickness of about 10 nm, performing etch back to the oxide film, and then ion implanting impurities at high concentrations.

In addition, the polycrystalline silicon for the gate electrodes may be doped into p-type to increase the threshold voltage. In such a case, it is necessary to nitride the gate oxide films or to replace each gate oxide film by a stacked film of a nitride film and an oxide film.

Furthermore, though the double gate transistor of the embodiment mentioned above is an NMOS, it may be manufactured as a PMOS. In such a case, if p-type polycrystalline silicon is used for the gate electrodes, it is necessary to nitride the gate oxide films or to replace each gate oxide film by a stacked film of a nitride film and an oxide film as for the above mentioned case.

What is claimed is:

1. A semiconductor device comprising:
a double gate transistor which comprises an active region of a fin type and a pair of gate electrodes disposed opposite to each other through said active region,
wherein a height of said gate electrodes is higher than a height of said active region so as to obtain an on-current larger than that of a case where the height of said gate electrodes is equal to the height of said active region.

2. A semiconductor device as claimed in claim 1, wherein the height of said gate electrodes is equal to or smaller than a calculated gate electrode height calculated using the following formula;
((Gate Electrode Height [nm])−(Active Region Height [nm]))/(Active Region Height ([nm])=3.5e⁻⁵×(Gate Length [nm])²−0.002×(Gate Length [nm])+0.16

3. A semiconductor device as claimed in claim 2, further comprising a hard mask formed on said active region and used for forming said active region,
wherein a position of upper surfaces of said gate electrodes is matched with that of an upper surface of said hard mask.

4. A semiconductor device as claimed in claim 1, further comprising a hard mask formed on said active region and used for forming said active region,
wherein a position of upper surfaces of said gate electrodes is matched with that of an upper surface of said hard mask.

5. A manufacturing method of a semiconductor device which includes a double gate transistor, said double gate transistor comprising an active region of a fin type and a pair of gate electrodes disposed opposite to each other through said active region, said manufacturing method comprising steps of:
adjusting, to a predetermined value, a thickness of a hard mask which is formed on said active region and used for forming said active region;
forming an electrode layer for said gate electrodes;
polishing said electrode layer so that a position of an upper surface thereof is matched with that of an upper surface of said hard mask to form said gate electrodes.

6. A manufacturing method as claimed in claim 5, wherein the predetermined value is determined so that a height of said gate electrodes is equal to or smaller than a calculated gate electrode height calculated using the following formula:
$$( ( Gate Electrode Height [ nm ] ) - ( Active Region Height [ nm ] ) ) / ( Active Region Height [ nm ] ) = 3.5 {e}^{- 5} \times {( Gate Length [ nm ] )}^{2} - 0.002 \times ( Gate Length [ nm ] ) + 0.16$$

7. A manufacturing method as claimed in claim 6, wherein said polishing step is executed with chemical mechanical polishing using said hard mask as an end point detection film.

8. A manufacturing method as claimed in claim 5, wherein said polishing step is executed with chemical mechanical polishing using said hard mask as an end point detection film.
